(19) United States
(12) Patent Application Publication
(10) Pub. No.: US 2022/0311204 A1
(43) Pub. Date: Sep. 29, 2022

(54) LIGHT-EMITTING DEVICE

(71) Applicant: NICHIA CORPORATION, Anan-shi (JP)

(72) Inventors: Soichiro MIURA, Tokushima-shi (JP); Takuya HASHIMOTO, Tokushima-shi (JP)

(73) Assignee: NICHIA CORPORATION, Anan-shi (JP)

(21) Appl. No.: 17/703,165

(22) Filed: Mar. 24, 2022

(30) Foreign Application Priority Data
Mar. 26, 2021 (JP) 2021-052627

(51) Int. Cl. H01S 5/0233; H01L 33/48; H01L 33/60; H01S 5/02326; G02B 27/14

(52) U.S. Cl. CPC H01S 5/0233; H01L 33/483; H01L 33/60; H01S 5/02326; G02B 27/141

(57) ABSTRACT

A light-emitting device includes: a first light-emitting element including a first light-emission surface through which first light is emitted along a first optical axis; a second light-emitting element disposed apart from the first light-emitting element in a first direction that is perpendicular to the first optical axis, the second light-emitting element including a second light-emission surface through which second light is emitted along a second optical axis that is inclined with respect to the first optical axis in a second direction opposite to the first direction; and a third light-emitting element disposed apart from the first light-emitting element in the second direction, wherein the third light-emitting element includes a third light-emission surface through which third light is emitted along a third optical axis that is inclined with respect to the first optical axis in the first direction.

### CROSS-REFERENCE TO RELATED APPLICATION

This application claims priority to Japanese Patent Application No. 2021-052627, filed on Mar. 26, 2021, the entire contents of which are hereby incorporated by reference.

### BACKGROUND

The present disclosure relates to a light-emitting device.

Light-emitting devices that include a plurality of light-emitting elements to emit light of respectively different central wavelengths have been developed. For example, Japanese Patent Publication No. 2001-291259 discloses a light-emitting device that includes a plurality of semiconductor laser elements, and a collimate lens through which laser light emitted from each semiconductor laser element passes. This light-emitting device is an optical pickup device that allows laser light that is selectively emitted from a respective one of the plurality of semiconductor laser elements of different lasing wavelengths to be converged on a CD or a DVD. In this light-emitting device, the positions of the plurality of semiconductor laser elements are adjusted so as to correct for misalignments in respective focal points.

### SUMMARY

There is a demand to reduce the size of light-emitting devices that include a plurality of light-emitting elements.

In one embodiment, a light-emitting device according to the present disclosure comprises a first light-emitting element including a first light-emission surface through which first light is emitted along a first optical axis; a second light-emitting element disposed apart from the first light-emitting element in a first direction that is perpendicular to the first optical axis such that a reference plane parallel to the first light-emission surface and intersecting the first light-emitting element intersects the second light-emitting element, the second light-emitting element including a second light-emission surface through which second light is emitted along a second optical axis that is inclined with respect to the first optical axis in a second direction opposite to the first direction; and a third light-emitting element disposed apart from the first light-emitting element in the second direction such that the reference plane intersects the third light-emitting element, wherein the third light-emitting element includes a third light-emission surface through which third light is emitted along a third optical axis that is inclined with respect to the first optical axis in the first direction.

With a light-emitting device according to the present disclosure, points of incidence of light emitted from a plurality of light-emitting elements can be brought closer together on an incident surface of a lens member than in the case where the plurality of light-emitting elements are disposed in parallel, whereby the light-emitting device can be downsized.

### BRIEF DESCRIPTION OF THE DRAWINGS

FIG. 1 is a perspective view of a light-emitting device according to a first embodiment or a second embodiment.

FIG. 2 is a perspective view of the light-emitting device according to the first embodiment, from which a cap of a package is omitted.

FIG. 3 is a top view of the light-emitting device according to the first embodiment, from which the cap of the package is omitted.

FIG. 4 is a cross-sectional view of the light-emitting device taken along cross-sectional line IV-IV in FIG. 1.

FIG. 5 is an enlarged top view of the inside of the package according to the first embodiment.

FIG. 6A is a top view schematically showing an optical axis of each of a plurality of light-emitting elements and light that is emitted from each light-emitting element along its optical axis.

FIG. 6B is a top view schematically showing the angle of the optical axis of each of a plurality of light-emitting elements.

FIG. 7A is a diagram schematically showing positional relationship of points of emission of first light, second light, and third light.

FIG. 7B is a diagram schematically showing positional relationship of points of incidence of first light, second light, and third light on an incident surface of a lens member.

FIG. 8 is a perspective view of the light-emitting device according to the second embodiment, from which a cap of a package is omitted.

FIG. 9A is a top view showing an exemplary shape of a submount on which a plurality of light-emitting elements are mounted, according to the second embodiment.

FIG. 9B is a top view showing positional relationship of points of emission of the plurality of light-emitting elements, according to the second embodiment.

FIG. 10 is a perspective view of a light-emitting device according to a third embodiment.

FIG. 11 is a top view of the light-emitting device according to the third embodiment, from which a cap of a package is omitted.

FIG. 12 is a perspective view of a light-emitting device according to a fourth embodiment.

FIG. 13 is a perspective view of the light-emitting device according to the fourth embodiment, from which a cover is omitted.

FIG. 14 is a perspective view of the light-emitting device according to the fourth embodiment, from which a second cap and the cover are omitted.

FIG. 15 is a top view of the light-emitting device according to the fourth embodiment, from which the second cap and the cover are omitted.

FIG. 16 is a perspective view of a substrate included in the light-emitting device according to the fourth embodiment.

FIG. 17 is a cross-sectional view of the light-emitting device according to the fourth embodiment, taken along cross-sectional line XVII-XVII in FIG. 15.

FIG. 18 is a side view of the light-emitting device according to the fourth embodiment, from which the second cap and the cover are omitted, as viewed from the cover side.

FIG. 19 is a cross-sectional view of a light-emitting device according to a fifth embodiment, taken along cross-sectional line XVII-XVII in FIG. 15.

FIG. 20 is a perspective view of a substrate included in the light-emitting device according to the fifth embodiment.

FIG. 21 is a schematic side view of a head-mounted display that includes a light-emitting device according to an embodiment of the present disclosure.

### DETAILED DESCRIPTION

In the present specification and in the claims, polygonal shapes such as triangles and quadrangles may include not only a polygonal shape in a strict sense but also include polygonal shapes with rounded corners, beveled corners, angled corners, reverse-rounded corners, etc. Not only shapes with such modification at corners (end of sides) but also shapes with modifications at intermediate portions of sides of the shapes are also referred to as “polygonal shapes.” That is, shapes that are based on polygonal shapes and partially modified are included in the term “polygonal shape” in the present specification and the claims.

This can be applied not only to polygonal shapes, but also to trapezoidal shapes, circular shapes, protrusions and recesses, and other terms indicating specific shapes. The same is also applied when referring to sides that form the shape. In other words, even if corner(s) or an intermediate portion of a side has been modified, the “side” is also inclusive of the modified portion(s). To distinguish a “polygon” or “side” without modification from those with a modification, the term “strict” may be used, e.g., a “strict quadrangle.”

In the present specification and in the claims, where there are a plurality of elements identified by a certain term and these element are to be expressed distinctly, the elements may be designated with “first,” “second,” and other ordinal numerals. For example, when a claim recites that “light-emitting elements are arranged on a substrate,” it may be described in the specification that “the first light-emitting element and the second light-emitting element are arranged on the substrate. The ordinal numerals “first” and “second” are merely used in order to distinguish between the two light-emitting elements. There is no special meaning for the order of these ordinal numerals. The designations of elements with the same ordinal numeral may refer to different elements between the specification and the claims. For example, when elements identified by the terms “first light-emitting element,” “second light-emitting element,” “third light-emitting element,” are described in the specification, the “first light-emitting element” and the “second light-emitting element” in the claims may correspond to the “first light-emitting element” and the “third light-emitting element” in the specification, respectively. In the case where the term “first light-emitting element” is used but the term “second light-emitting element” does not appear in claim 1, the invention according to claim 1 includes a light-emitting element, and the light-emitting element may be termed “first light-emitting element,” “second light-emitting element,” or “third light-emitting element” etc., in the specification.

In the present specification and in the claims, terms indicating specific directions or positions (e.g., “upper,” “above,” “over,” “lower,” “below,” “under,” “right,” “left,” “front,” and “rear,” or other terms using these terms) may be used. These terms are merely being used to indicate relative directions or positions in the referenced drawing, for ease of understanding. So long as relationship of relative directions or positions as indicated by terms such as “above,” “below,” etc., in the referenced drawing are consistent, corresponding components in drawings other than the present disclosure, actual products, production apparatuses, or the like may be arranged differently from those in the present disclosure.

Note that the dimensions, dimensional ratio, shapes, intervals of arrangement, etc. of components or parts shown in a drawing may be exaggerated for ease of understanding. In order to avoid excessive complexity of the drawings, certain elements may be omitted from illustration.

Hereinafter, certain embodiments of the present invention will be described with reference to the drawings. The embodiments described below are to give a concrete form to the technical ideas of the present invention, but the present invention is not limited thereto. The numerical values, shapes, materials, steps, and the order of the steps shown in the description of the embodiments are merely examples, and various modifications are possible so long as there is no technical contradiction. In the following description, elements identified by the same name or reference numerals are the same or the same type of elements, and redundant explanations of those elements may be omitted.

### First Embodiment

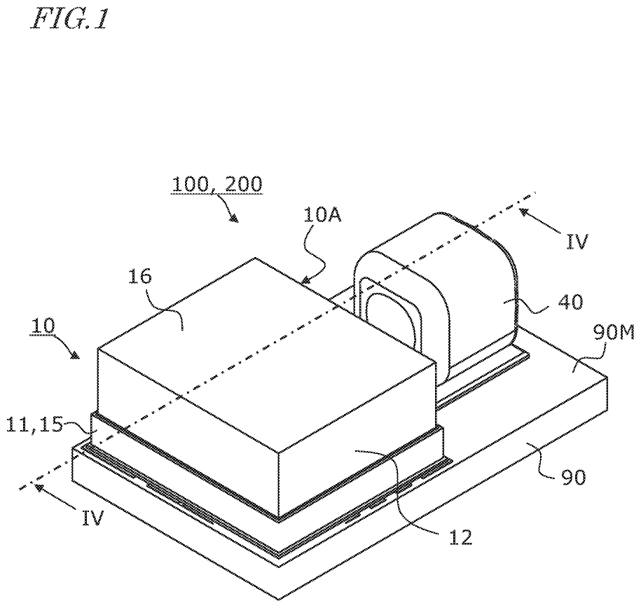

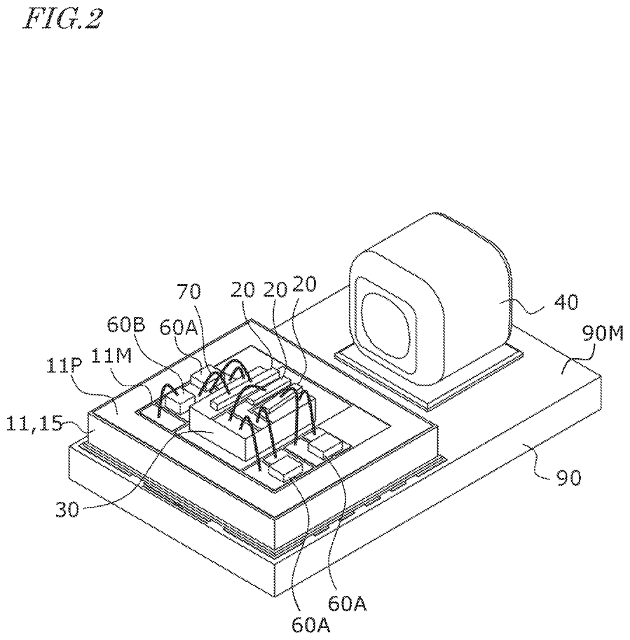

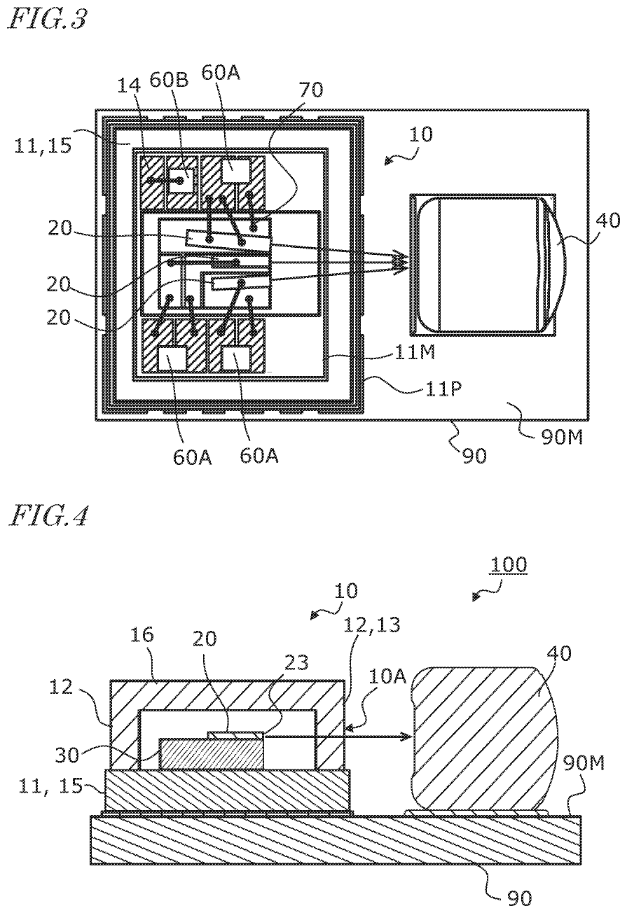

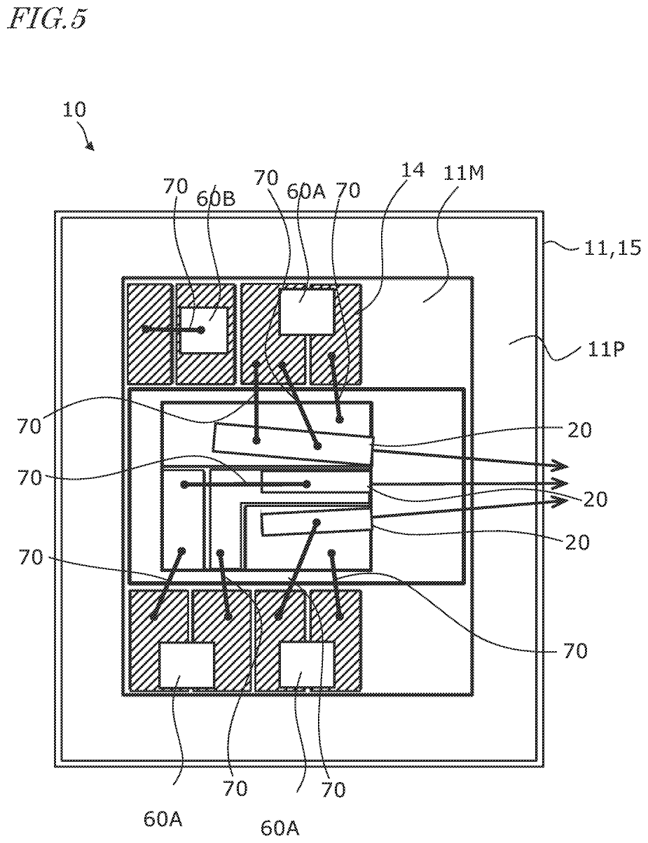

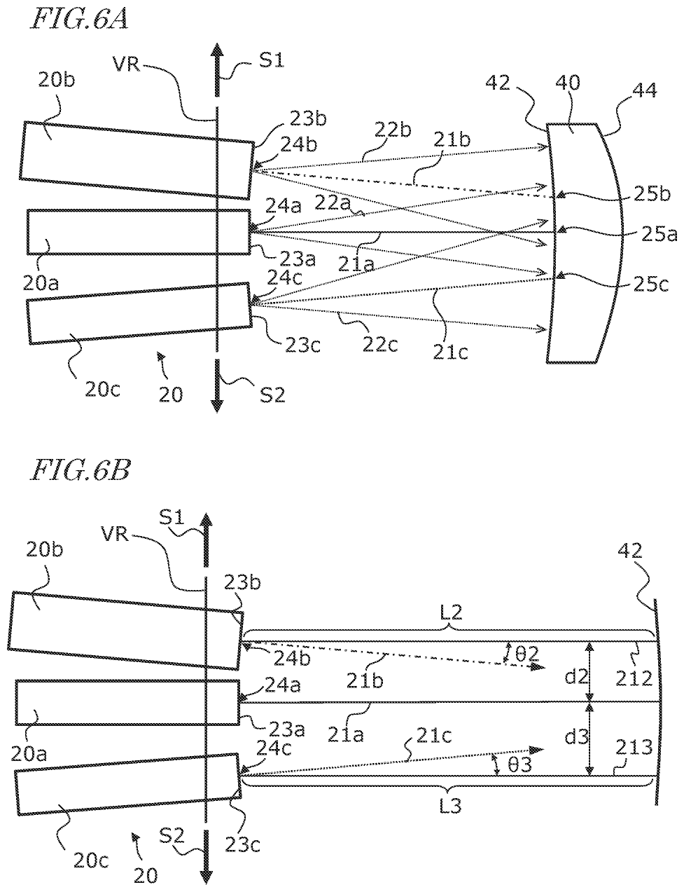

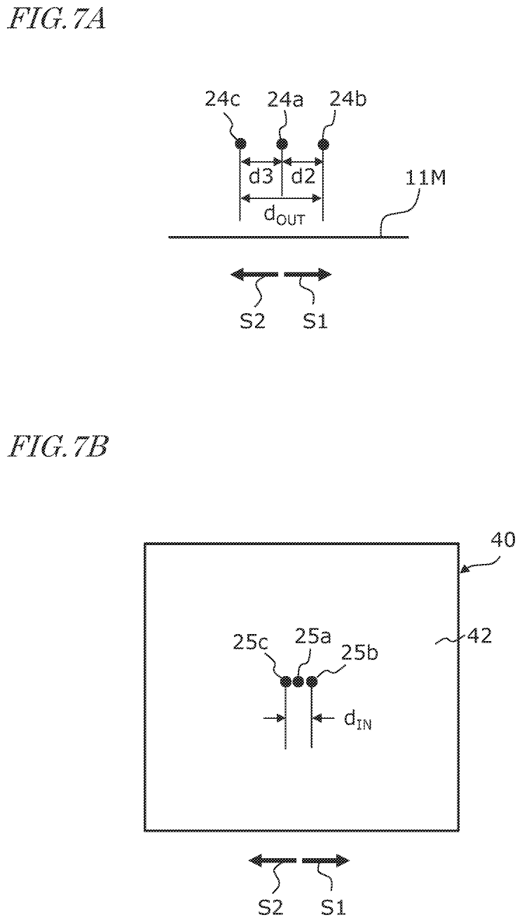

A light-emitting device 100 according to a first embodiment will be described. FIGS. 1 to 5, FIGS. 6A and 6B, and FIGS. 7A and 7B are diagrams showing an illustrative form of the light-emitting device 100. FIG. 1 is a schematic perspective view of the light-emitting device 100. FIG. 2 is a schematic perspective view of the light-emitting device 100, from which a cap 16 of a package 10 is omitted. FIG. 3 is a schematic top view of a state shown in FIG. 2. FIG. 4 is a schematic cross-sectional view taken along cross-sectional line IV-IV in FIG. 1. FIG. 5 is a schematic enlarged top view of the inside of the package 10. FIG. 6A is a top view schematically showing an optical axis of each of a plurality of light-emitting elements 20 and light that is emitted from each light-emitting element 20 along its optical axis. FIG. 6B is a top view schematically showing the angle of the optical axis of each of the plurality of light-emitting elements 20. FIG. 7A is a diagram schematically showing positional relationship of points of emission of first light, second light, and third light on a light-emission surface 23 of a light-emitting element 20. FIG. 7B is a diagram schematically showing relative positions of points of emission of first light, second light, and third light on the incident surface of the lens member 40.

The light-emitting device 100 includes a plurality of components, including: the package 10, one or more light-emitting elements 20, one or more submounts 30, the lens member 40, one or more protection elements 60A, a temperature measurement element 60B, a plurality of wirings 70, and a substrate 90. The light-emitting device 100 may include a plurality of light-emitting elements 20. The light-emitting device 100 may include a plurality of protection elements 60A.

In the illustrated example of the light-emitting device 100, the following are disposed within the space inside the package 10: three light-emitting elements 20, one submount 30, three protection elements 60A, one temperature measurement element 60B, and a plurality of wirings 70. Light that is emitted from each of the three light-emitting elements 20 is emitted from the package 10 to the outside, and thereafter is incident on the lens member 40. The light having been emitted from the three light-emitting elements 20 is collimated by the lens member 40.

Respective components will be described.

Package 10

The package 10 includes: a base portion 11, which includes a mounting surface 11M, and a lateral wall portion 12. In a top view, the package 10 has a rectangular outer shape. The outer shape of the package 10 does not need to be a rectangle, but may have other shape such as polygons other than a quadrangle, a circle, etc..

The mounting surface 11M is a flat surface, on which one or more components of the light-emitting device 100 are disposed. The lateral wall portion 12, surrounding the mounting surface 11M, extends upward from the mounting surface 11M. The one or more components disposed on the mounting surface 11M are surrounded by the lateral wall portion 12. The package 10 further includes an upper surface portion. The upper surface portion connects to the lateral wall portion 12, at a location above the mounting surface 11M. The upper surface portion is located immediately above the one or more components disposed on the mounting surface 11M.

The package 10 includes a plurality of wiring regions 14 for establishing electrical connection. The wiring regions 14 are provided on the mounting surface 11M. In FIG. 3 and FIG. 5, each wiring region 14 is shown with hatchings. Through via holes extending inside the base portion 11, the a plurality of wiring regions 14 may be electrically connected to wiring regions that are provided on a lower surface (i.e., the opposite surface to the mounting surface 11M) of the base portion 11. Other than the lower surface of the base portion 11, such wiring regions to be electrically connected to the wiring regions 14 may be provided on other external surface (the upper surface or an outer lateral surface) of the package 10.

The package 10 includes a light extraction surface 10A. The light extraction surface 10A may be one of the one or more outer lateral surfaces constituting the lateral wall portion 12. The light extraction surface 10A stands generally upright from the mounting surface 11M. The light extraction surface 10A may be perpendicular to a plane that is parallel to the mounting surface 11M. As used herein, the term “perpendicular” includes a difference within ±5 degrees. The light extraction surface 10A may be inclined from the plane that is parallel to the mounting surface 11M.

At least a partial region of the light extraction surface 10A is light-transmissive. This light-transmitting region will be referred to as a light-transmissive region 13 (see FIG. 4 for the numeral “13”). The term “light-transmissive” refers to that a main portion of light entering the region has a transmittance of 80% or greater. The light-transmissive region 13 may extend over a plurality of outer lateral surfaces of the package 10.

The light-transmissive region in the package 10 is not limited to the light-transmissive region 13. For example, a surface other than the light extraction surface 10A may include light-transmissive region(s) separately from the light-transmissive region 13, on. The package 10 may include a non-light-transmissive regions (i.e., region(s) that are not of light-transmissive nature).

In the illustrated example of the package 10, only one of the outer lateral surfaces constituting the lateral wall portion 12 is the light extraction surface 10A. The package 10 includes four outer lateral surfaces corresponding to the rectangular outer shape, all of these four surfaces being light-transmissive.

The package 10 may be composed of a substrate 15 and a cap 16 fixed to the substrate 15. The package 10 may also include any additional components. The substrate 15 includes the base portion 11, whereas the cap 16 includes the lateral wall portion 12 and the upper surface portion. The substrate 15 has a flat plate shape. The cap 16 has a recessed shape defining a recess. The outer shape of the cap 16 is rectangular in a top view. The outer shape of the cap 16 does not need to be rectangular; for example, it may be a polygonal shape other than a quadrangle, a circular shape.

The cap 16 is bonded to the substrate 15 to define an internal space in the package 10. A peripheral region 11P is provided on the mounting surface 11M of the substrate 15. The peripheral region 11P is provided around a region of the mounting surface 11M where other components are disposed. The wiring regions 14 are surrounded by the peripheral region 11P. The cap 16 is bonded to the peripheral region 11P of the substrate 15. A metal film for bonding may be disposed in the peripheral region 11P. The internal space of the package 10 is a sealed space. The internal space of the package 10 is in a hermetically sealed state.

The cap 16 may be made of a light-transmissive material, for example. The cap 16 may have a structure in which only the lateral wall portion 12 is made [BCJ [symbol] 2][O3]of a light-transmissive material; for example, the upper surface portion may be made of a non-light-transmissive material.

The substrate 15 may be made of a ceramic as a main material. Examples of ceramics to be used as the main material of the substrate 15 include aluminum nitride, silicon nitride, aluminum oxide, and silicon carbide. The substrate 15 may be made of a ceramic substrate that has a plurality of metal vias inside. The wiring regions 14 may be a patterned metal film that is made of an electrical conductor, e.g., a metal.

The cap 16 may be produced from a light-transmissive material such as glass, plastic, or quartz, by using a processing technique such as molding or etching. The cap 16 may be formed by first forming the upper surface portion and the lateral wall portion 12 by using different materials as their main materials, and bonding them together. For example, the main material of the upper surface portion may be monocrystalline or polycrystalline silicon, while the main material of the lateral wall portion 12 may be glass.

The internal space of the package 10 may be made by any method other than by using a plate-shaped member having the mounting surface 11M and a recessed-shaped member, e.g., the substrate 15 and the cap 16. For example, the internal space of the package 10 may be formed of a concave-shaped member having the mounting surface 11M and a plate-shaped member. Alternatively, for example, the internal space of the package 10 may be formed of two concave-shaped members, one of which has the mounting surface 11M.

Hereinafter, in order to distinguish the substrate 15 and the substrate 90 from each other, they may be respectively referred to as the first substrate 15 and the second substrate 90.

(Light-Emitting Element 20)

An example of a light-emitting element 20 is a semiconductor laser element. The light-emitting element 20 may have a rectangular outer shape in a top view. In the case where the light-emitting element 20 is an edge-emitting type semiconductor laser element, a lateral surface that intersects one of the two shorter sides of the rectangle defines an emission end surface through which light is emitted (light-emission surface 23). The light-emitting element 20 emits light through the light-emission surface 23. In this example, an upper surface and a lower surface of the light-emitting element 20 each have a greater area than that of the light-emission surface 23. Without being limited to an edge-emitting type semiconductor laser element, the light-emitting element 20 may be a semiconductor laser element of a surface emitting type, or a light-emitting diode (LED). In the illustrated example of the light-emitting device 100, an edge-emitting type semiconductor laser element is employed as the light-emitting element 20.

The light-emitting element 20 according to the present embodiment is a single-emitter element (i.e., having one emitter). Note that the light-emitting element 20 may be a multi-emitter element (i.e., having two or more emitters). In the case where the light-emitting element 20 is a semiconductor laser element having a plurality of emitters, one common electrode may be provided on one of the upper surface and the lower surface of the light-emitting element 20, and electrodes corresponding to the respective emitters may be provided on the other one of the upper surface and the lower surface.

The light that is emitted from the light-emission surface 23 of the light-emitting element 20 is divergent light having some spread. Alternatively, the light may not be divergent light. In the case where the light-emitting element 20 is a semiconductor laser element, the light (laser light) that is emitted from the semiconductor laser element creates a far field pattern (hereinafter referred to as “FFP”) of an elliptical shape at a surface that is parallel to the light-emission surface 23. The term FFP refers to the shape, or optical intensity distribution, of emitted light at a position apart from the light-emission surface.

Light that passes through the center of the elliptical shape of an FFP, i.e., light having a peak intensity in the optical intensity distribution of the FFP, will be referred to as “light traveling on an optical axis.” Moreover, the optical path of light traveling on an optical axis will be referred to as “the optical axis” of that light. In the optical intensity distribution of an FFP, light having an intensity that is 1/e² or greater with respect to the peak intensity value may be referred to as the “main portion” of light.

In the elliptical shape of an FFP of light that is emitted from the light-emitting element 20 being a semiconductor laser element, the minor axis direction of the ellipse will be referred to the “slow-axis direction,” and its major axis direction will be referred to as the “fast-axis direction.” The plurality of layers that compose the semiconductor laser element (including an active layer) are layered in the fast-axis direction.

Based on the optical intensity distribution of an FFP, an angle corresponding to an intensity that is 1/e² with respect to the peak intensity value of the optical intensity distribution is defined as an angle of spread of the light from the semiconductor laser element. The main portion of light emitted from the semiconductor laser element is divergent light that spreads with the angle of spread. An angle of spread of light along the fast-axis direction may be referred to as an “angle of spread along the vertical direction,” whereas an angle of spread of light along the slow-axis direction may be referred to as an “angle of spread along the horizontal direction.”

As the light-emitting element 20, for example, a light-emitting element emitting blue light, a light-emitting element emitting green light, a light-emitting element emitting red light, or the like may be employed. Light-emitting element emitting any other colors of light may also be employed as the light-emitting element 20.

Herein, blue light refers to light that falls within an emission peak wavelength range from 420 nm to 494 nm. Green light refers to light that falls within an emission peak wavelength range from 495 nm to 570 nm. Red light refers to light that falls within an emission peak wavelength range from 605 nm to 750 nm.

Examples of semiconductor laser element emitting blue light or semiconductor laser elements emitting green light may be semiconductor laser elements containing a nitride semiconductor. As the nitride semiconductor, for example, GaN, InGaN, or AlGaN may be used. Examples of semiconductor laser elements emitting red light may be those containing an InAlGaP-based, GaInP-based, GaAs-based, or AlGaAs-based semiconductor.

(Submount 30)

The submount 30 has two bonding surfaces, and is shaped as a rectangular solid. At the opposite side to one bonding surface, the other bonding surface is provided. The distance between these two bonding surfaces is shorter than the distance between any other pair of two opposing surfaces. The shape of the submount 30 is not limited to a rectangular solid. The submount 30 may be made of aluminum nitride or silicon carbide. A metal film for bonding purposes is provided on the bonding surface.

(Lens Member 40)

The lens member 40 is formed so as to have one or more lens surfaces. The lens member 40 collimates light incident thereon. For example, the one or more lens surfaces may be designed so as to convert light (that diverges from the focal point) into collimated light through refraction, and emit the light through the lens member 40. Each lens surface may be spherical or aspherical. A lens surface(s) may be formed on the surface at the light-entering side of the lens member 40 and/or the surface at the light-emission side of the lens member 40. In the illustrated example of the lens member 40, a concave lens surface is formed on the light-entering side, and a convex lens surface is formed on the light-emission side. Note that a plurality of lens surfaces may be formed on the light-entering surface; that is, one or more lens surfaces may be formed on the light-entering surface of the lens member 40. Note that a plurality of lens surfaces may be formed on the light-emission surface; that is, one or more lens surfaces may be formed on the light-emission surface of the lens member 40.

The lens member 40 may be made of a light-transmissive material, e.g., glass or plastic. Although the portion of the lens member 40 through which light is not transmitted may have any appropriate shape, it preferably has a shape that allows the lens member 40 to be fixed to other components. In the illustrated example of the lens member 40, when its optical axis is disposed so as to extend in parallel to the lower surface of the lens member 40, the lens member 40 has a flat lower surface, such that this lower surface may function as a bonding surface.

(Protection Element 60A)

The protection elements 60A are circuit elements to prevent flow of excessive current into certain devices (e.g., a light-emitting element 20) that may result in destruction. A typical example of a protection element 60A is a voltage regulating diode such as a Zener diode. As a Zener diode, a Si diode may be employed.

(Temperature Measurement Element 60B)

The temperature measurement element 60B is a device used as a temperature sensor for measuring the surrounding temperature. As the temperature measurement element 60B, a thermistor may be used, for example.

(Wiring 70)

Each wiring 70 is made of an electrical conductor having a linear shape, both ends of which serve as bonding sites. In other words, the wiring 70 has, at both ends of its linear body, bonding sites for bonding to other components. The wiring 70 may be a metal wire, for example. Examples of metals include gold, aluminum, silver, and copper.

(Second Substrate 90)

The second substrate 90 has a mounting surface 90M. The second substrate 90 includes a plurality of wiring regions. The plurality of wiring regions may be provided on the mounting surface 90M. The wiring regions of the second substrate are respectively electrically connected to wiring regions provided on the lower surface (i.e., the opposite surface to mounting surface 90M) of the second substrate 90 through the second substrate 90. Other than the lower surface of the second substrate 90, the wiring regions to be electrically connected to the wiring regions disposed on the upper surface (mounting surface 90M) of the second substrate 90 may be provided on other external surface (e.g., an upper surface or outer lateral surfaces) of the second substrate 90.

The second substrate 90 can be formed by using a ceramic as a main material. Examples of ceramics to be used for the second substrate 90 include aluminum nitride, silicon nitride, aluminum oxide, and silicon carbide.

The second substrate 90 preferably includes a portion that is made of a material that is superior in heat-releasing ability to ceramics (i.e., a material of high thermal conductivity). In the exemplary second substrate 90, the second substrate 90 may include a heat-conductive member embedded inside. Such a heat-conductive member fills an opening penetrating from the upper surface to the lower surface of the second substrate 90. The heat-conductive member may be provided in a region facing to the lower surface of the first substrate 15. The heat-conductive member may be made of a metal, for example. The heat-conductive member 97 may have any appropriate shape.

The second substrate 90 is structured so as to support the components of the light-emitting device 100, and to be capable of electrically connecting with electronic parts included in such components. The second substrate 90 may also support any elements, electronic parts, or optical parts other than the components of the light-emitting device 100.

(Light-Emitting Device 100)

Next, the light-emitting device 100 will be described.

In the light-emitting device 100, the one or more light-emitting elements 20 are disposed in the internal space of the package 10. For example, by hermetically sealing the internal space of the package 10, deteriorations in quality due to collection of dust in the light-emitting element 20 can be restrained. Such a sealing structure is preferable in the case where the light-emitting element 20 is a semiconductor laser element, for example. Note that the light-emitting element 20 does not need to be in a sealed internal space.

The one or more light-emitting elements 20 are disposed on the mounting surface 11M. The one or more light-emitting elements 20 emit light toward the lateral wall portion 12. The light emitted through the light-emission surface(s) 23 of the one or more light-emitting elements 20 is each emitted through the light-transmissive region 13 of the light extraction surface 10A.

In the illustrated example of the light-emitting device 100, the plurality of light-emitting elements 20 are disposed on the mounting surface 11M. The plurality of light-emitting elements 20 emit light of respectively different peak wavelengths. The plurality of light-emitting elements 20 emit light of respectively different colors. The plurality of light-emitting elements 20 include a first light-emitting element 20a, a second light-emitting element 20b, and a third light-emitting element 20c. The first light-emitting element 20a is located in the middle, so as to be flanked by the second light-emitting element 20b and the third light-emitting element 20c.

The one or more light-emitting elements 20 are disposed so that their light-emission surfaces 23 face the light extraction surface 10A. The light traveling on the optical axis, emitted from each light-emitting element 20, travels from the light extraction surface 10A in a parallel direction to the mounting surface 11M. As used herein, being “parallel” admits of a difference within ±3 degrees. The light extraction surface 10A is perpendicular to the optical axis along which light emitted from the light-emitting element 20 travels. The light extraction surface 10A does not need to be perpendicular to the optical axis along which the light emitted from one or more light-emitting elements 20 travels.

In the illustrated example of the light-emitting device 100, the light extraction surface 10A is perpendicular to the optical axis along which (hereinafter, the “first optical axis 21a”) the light emitted from the first light-emitting element 20a (hereinafter, the “first light 22a”) travels. Examples of the first light 22a and the first optical axis 21a are illustrated in FIG. 6A.

Next, with reference to FIG. 6A and FIG. 6B, an exemplary arrangement of the plurality of light-emitting elements 20 will be described in more detail, in relation to the lens member 40. The first light-emitting element 20a includes a first light-emission surface 23a, through which the first light 22a is emitted along the first optical axis 21a. The first optical axis 21a is preferably parallel to the optical axis of the lens member 40, and more preferably identical to the optical axis of the lens member 40. In the illustrated example, the first optical axis 21a is identical to the optical axis of the lens member 40. In the present disclosure, two optical axes being identical means that the two optical axes are parallel and that the center-to-center distance between the two optical axes is 0.1 mm or less. When traveling along the first optical axis 21a, the first light 22a spreads out in directions orthogonal to the first optical axis 21a.

The second light-emitting element 20b is disposed at a position that is intersected by a plane VR that is parallel to the first light-emission surface 23a of the first light-emitting element 20a and that passes through the first light-emitting element 20a. More specifically, the second light-emitting element 20b is disposed at a position that is intersected by the plane VR and that is apart from the first light-emitting element 20a in a first direction S1 that is perpendicular to the first optical axis 21a. The second light-emitting element 20b includes a second light-emission surface 23b, through which light (hereinafter, the “second light 22b”) is emitted along an optical axis (hereinafter, the “second optical axis 21b”) that is inclined relative to the first optical axis 21a in a second direction S2, the second direction S2 being opposite to the first direction S1. When traveling along the second optical axis 21b, the second light 22b spreads out in directions orthogonal to the second optical axis 21b.

The third light-emitting element 20c is disposed at a position that is intersected by the plane VR and that is separated from the first light-emitting element 20a in the second direction S2 perpendicular to the first optical axis 21a (i.e., the second direction S2 is an antiparallel direction to the first direction S1). The third light-emitting element 20c includes a third light-emission surface 23c through which light (hereinafter, the “third light 22c”) is emitted along an optical axis (hereinafter, the “third optical axis 21c”) that is inclined relative to the first optical axis 21a in the first direction S1. When traveling along the third optical axis 21c, the third light 22c spreads out in directions orthogonal to the third optical axis 21c.

FIG. 6A shows a first point of emission 24a at which the first light 22a traveling along the first optical axis 21a is emitted through the first light-emission surface 23a, a second point of emission 24b at which the second light 22b traveling along the second optical axis 21b is emitted through the second light-emission surface 23b, and a third point of emission 24c at which the third light 22c traveling along the third optical axis 21c is emitted through the third light-emission surface 23c. In this example, the distance between the plane VR and each of the first point of emission 24a, the second point of emission 24b, and the third point of emission 24c is substantially equal. As will be described later, this is not the only example of a light-emitting device according to the present disclosure.

FIG. 6B shows an imaginary line 212 that is parallel to the first optical axis 21a and that extends from the second point of emission 24b. The angle 02 between the imaginary line 212 and the second optical axis 21b defines an inclination of the second optical axis 21b with respect to the first optical axis 21a. In a top view and with respect to the direction of the first optical axis 21a, counterclockwise rotation (i.e., rotation within a plane that is parallel to the mounting surface 11M) may be defined as “positive” rotation, whereas clockwise rotation may be defined as “negative” rotation; under these definitions, the angle θ2 has a negative value. The angle θ2 has an absolute value (|θ2|) in the range of greater than 0 degrees and 30 degrees or less. A preferable range of the absolute value of the angle θ2 is e.g., 3 degrees or greater and 15 degrees or less.

FIG. 6B shows an imaginary line 213 that is parallel to the first optical axis 21a and that extends from the third point of emission 24c. The angle θ3 between the imaginary line 213 and the third optical axis 21c defines an inclination of the third optical axis 21c with respect to the first optical axis 21a. Based on the above definitions, the angle θ3 has a positive value. The value of the angle θ3 (which is equal to the absolute value |θ3| of the angle θ3) is in the range greater than 0 degrees and 30 degrees or less. A preferable range of the angle θ3 is e.g., 3 degrees or greater and 15 degrees or less.

The difference between the absolute value of the angle θ2 and the absolute value of the angle θ3 is in the range of 0 degrees or greater and 5 degrees or less. In the illustrated example of the light-emitting device 100, the absolute value of the angle θ2 and the absolute value of the angle θ3 are equal. In other words, the difference between the angle θ2 and the angle θ3 is 0 degrees. As used herein, the term “equal” includes a difference within 1 degree. The distance d2 from the first point of emission 24a to the second point of emission 24b is equal to the distance d3 from the first point of emission 24a to the third point of emission 24c. As used herein, the term “equal” includes a difference within 50 μm. Although the distance d2 and the distance d3 do not need to be equal, the difference between the distance d2 and the distance d3 is preferably within 300 μm. The smaller the difference in distance is, the smaller the difference in angle is, thereby facilitating the optical control with the lens member 40 or like elements. The second optical axis 21b and the third optical axis 21c are of a symmetric relationship or a substantially symmetric relationship with respect to the first optical axis 21a. The distance from each of the first point of emission 24a, the second point of emission 24b, and the third point of emission 24c to the plane VR is equal. As used herein, the term “equal” includes a difference within 20 μm. The distance L2 from the second light-emission surface 23b to the light-incident surface 42 of the lens member 40 is substantially equal to the distance L3 from the third light-emission surface 23c to the light-incident surface 42 of the lens member 40. As will be described later, depending on the arrangement of the three light-emitting elements 20, the absolute value of the angle θ2 and the absolute value of the angle θ3 may be different.

Peak wavelengths of the first light 22a, the second light 22b, and the third light 22c will be referred to as the first peak wavelength, the second peak wavelength, and the third peak wavelength, respectively. In the light-emitting device 100, the first light 22a, the second light 22b, and the third light 22c may be light of respectively different colors selected from among red light, green light, and blue light.

In one example, the first light-emitting element 20a may radiate first light 22a being a green light, and the two light-emitting elements 20b and 20c at both sides of the first light-emitting element 20a may respectively radiate second light 22b being a red light and third light 22c being a blue light. Thus, an implementation in which the three light-emitting elements 20 are composed of light of the three colors of RGB may be employed for applications of color image displaying, for example. Note that the colors of light to be emitted from the respective light-emitting elements 20 are not limited to these, and are not limited to visible light.

The light-emitting device 100 is configured so that, in a top view, the first light 22a traveling along the first optical axis 21a and the second light 22b traveling along the second optical axis 21b intersect each other, in an optical path from the incident surface 42 to the exit surface 44 of the lens member 40. In a top view, the first light 22a traveling along the first optical axis 21a and the third light 22c traveling along the third optical axis 21c intersect each other in an optical path from the incident surface 42 to the exit surface 44 of the lens member 40. In a top view, the second light 22b traveling along the second optical axis 21b and the third light 22c traveling along the third optical axis 21c intersect each other in an optical path from the incident surface 42 to the exit surface 44 of the lens member 40.

The first point of incidence 25a at which the first light 22a traveling along the first optical axis 21a is incident on the incident surface 42 of the lens member 40, the second point of incidence 25b at which the second light 22b traveling along the second optical axis 21b is incident on the incident surface 42 of the lens member 40, and the third point of incidence 25c at which the third light 22c traveling along the third optical axis 21c is incident on the incident surface 42 of the lens member 40 are closer together than are the first point of emission 24a at which the first light 22a traveling along the first optical axis 21a is emitted through the first light-emission surface 23a, the second point of emission 24b at which the second light 22b traveling along the second optical axis 21b is emitted through the second light-emission surface 23b, and the third point of emission 24c at which the third light 22c traveling along the third optical axis 21c is emitted through the third light-emission surface 23c.

In the example illustrated in FIG. 7A, the most distant interval between points of emission among the first point of emission 24a, the second point of emission 24b, and the third point of emission 24c is a distance d_{OUT}. The distance d_{OUT} is a sum of the aforementioned distance d2 and the distance d3. On the other hand, in the example illustrated in FIG. 7B, the most distant interval between points of incidence among the first point of incidence 25a, the second point of incidence 25b, and the third point of incidence 25c is a distance d_{IN}. According to the present embodiment, the distance d_{IN} can be made shorter than the distance d_{OUT}. The distance d_{IN} is e.g., 0 μm or greater and 500 μm or less. The distance d_{IN} may have any value smaller than the distance d_{OUT}; the minimum value of the distance d_{IN} may be e.g., 0 μm. Herein, d_{IN}=0 μm would mean that the first point of incidence 25a, the second point of incidence 25b, and the third point of incidence 25c all coincide at one point. The distance d_{IN} may be equal to or less than a half of the distance d_{OUT}. The distance d_{OUT} may be e.g., greater than 0 μm and 1000 μm or less.

Thus, the effect of reducing the distance d_{IN} is to allow the points of incidence of light respectively emitted from the plurality of light-emitting elements 20 in different positions to be closer to the optical axis of the lens member 40. By bringing these points of incidence closer to the optical axis, the accuracy of optical control can be improved. For example, in general, as the point of incidence of light becomes more distant from the optical axis of the lens member 40, spherical aberration exerts a greater influence. According to the present embodiment, the points of incidence of light emitted from the plurality of light-emitting elements 20 can be made identical or close to the optical axis of the lens member 40. Moreover, by reducing the distance d_{IN}, when a color image is produced by using the light-emitting device according to the present embodiment as a light source, pixel misalignments from color to color can be reduced.

In the example of FIG. 7A, the positions of the first point of emission 24a, the second point of emission 24b, and the third point of emission 24c along the vertical direction (i.e., height from the mounting surface 11M) are illustrated as equal; however, embodiments of the present disclosure are not limited to this example. Similarly, in the example of FIG. 7B, the positions of the first point of incidence 25a, the second point of incidence 25b, and the third point of incidence 25c along the vertical direction are illustrated as equal; however, embodiments of the present disclosure are not limited to this example.

The light-emitting device 100 includes one or more light-emitting elements 20 being disposed on one or more submounts 30. The submount(s) 30 is bonded to the light-emitting element(s) 20 at one of its bonding surface, and is bonded to the mounting surface 11M at its opposite bonding surface. Note that the one or more light-emitting elements 20 may be disposed directly on the mounting surface 11M, rather than via a submount 30. In the illustrated example of the light-emitting device 100, a plurality of light-emitting elements 20 are disposed on a single submount 30.

In the light-emitting device 100, the one or more protection elements 60A are disposed inside the package 10. Each protection element 60A is disposed on the mounting surface 11M. Different protection elements 60A are to be disposed in different wiring regions 14. The light-emitting element 20 is protected by the protection element 60A. In the illustrated example of the light-emitting device 100, a plurality of protection elements 60A are provided in a one-to-one relationship for a plurality of light-emitting elements 20.

In the light-emitting device 100, the temperature measurement element 60B is disposed inside the package 10. The temperature measurement element 60B is disposed on the mounting surface 11M. The temperature measurement element 60B is disposed in a wiring region 14 in which no protection element 60A is disposed. The temperature measurement element 60B is provided in the light-emitting device 100 for the purpose of measuring the temperature of the light-emitting element(s) 20.

In the light-emitting device 100, in a top view, each wiring 70 is bonded to a wiring region 14 of the package 10 on a side of a straight line (running parallel to the light-emission surface 23 of the light-emitting element 20) that is on the light-emitting element 20 side (i.e., the side including the opposite surface of the light-emitting element 20 from the light-emission surface 23). This makes it easier to avoid the presence of the wiring 70 in the optical path of light.

In the light-emitting device 100, the package 10 is disposed on the second substrate 90. The lower surface of the package 10 is mounted to the mounting surface 90M of the second substrate 90, whereby the package 10 becomes supported by the second substrate 90. The lower surface of the package 10 may also be the lower surface of the first substrate 15.

Each of the light-emitting element(s) 20, the protection element(s) 60A, and the temperature measurement element 60B are electrically connected to the second substrate 90 via a wiring region 14, and may further be electrically connected to circuitry that is external to the light-emitting device 100 via a plurality of wiring regions of the second substrate 90.

In the light-emitting device 100, in a top view, the second substrate 90 has a greater length along a perpendicular direction to the first direction S1 than a length along a parallel direction to the first direction S1. The length of a longer side of the second substrate 90 may be equal to or greater than 1.5 times the length of a shorter side and equal to or less than 3 times the length of a shorter side. As will be described in detail later, when the light-emitting device 100 is mounted in a head-mounted display 600 in a manner shown in FIG. 21, it is advantageous that the length along the parallel direction to the first direction S1 and the second direction S2 is shorter.

Hereinafter, the mounting surface 11M of the first substrate 15 and the mounting surface 90M of the second substrate 90 may be distinguished as the first mounting surface 11M and the second mounting surface 90M, respectively.

In the light-emitting device 100, the lens member 40 is disposed on the second substrate 90. The lens member 40 is mounted on the second mounting surface 90M, whereby the lens member 40 becomes supported by the second substrate 90. Note that the lens member 40 may alternatively be mounted on the first substrate 15. By taking the illustrated example of the light-emitting device 100 for instance, the first substrate 15 may be made as large as the second substrate 90, such that the first substrate 15 extends over to where the lens member 40 is disposed, whereby the lens member 40 can be mounted on the first substrate 15.

The lens member 40 is disposed outside the package 10. Therefore, the lens member 40 is not surrounded by the lateral wall portion 12. By not disposing the lens member 40 in the internal space of the package 10, the size of the package 10 along its height direction (i.e., the direction perpendicular to the first mounting surface 11M) can be reduced, thus contributing to the downsizing of the light-emitting device 100.

The lens member 40 is struck by light that is emitted from the one or more light-emitting elements 20 and emitted through the light extraction surface 10A to the outside of the package 10. All of the main portions of light emitted from the one or more light-emitting elements 20 is incident on the lens member 40. Additionally, the remainder (i.e., other than the main portions) of light emitted from the one or more light-emitting elements 20 may also be incident on the lens member 40.

Light that is emitted from the one or more light-emitting elements 20 and emitted from the light-transmissive region 13 to the outside of the package 10 is incident on the lens member 40, so as to be emitted through one lens surface thereof. The light from the one or more light-emitting elements 20 having been incident on the incident surface of the lens member 40 becomes collimated light, and is emitted through the exit surface of the lens member 40. Specifically, the light from the one or more light-emitting elements 20 having been incident on the incident surface of the lens member 40 becomes light that is collimated regarding its fast-axis direction, and is emitted through the exit surface of the lens member 40. Collimating the light from the plurality of light-emitting elements 20 through one lens surface allows the intervals between the light-emitting elements 20 to be narrowed, thus contributing to the downsizing of the light-emitting device 100.

The lower surface of the lens member 40 is located below a plane containing the first mounting surface 11M. A part of the main portion of light emitted through the light extraction surface 10A passes below the plane containing the first mounting surface 11M, at a position that is closer to the light extraction surface 10A than is the incident surface of the lens member 40. Bonding the package 10 and the lens member 40 to the second substrate 90 allows the lower surface of the lens member 40 to be in a position that is lower than the first mounting surface 11M, whereby light traveling at a lower position than the plane containing the first mounting surface 11M is allowed to be incident on the lens member 40.

The optical axis of the lens surface of the lens member 40 through which light is emitted and the optical axis of light extracted through the light extraction surface 10A are at the same height from the first mounting surface 11M of the base portion 11. The optical axis of the lens surface of the lens member 40 through which light is emitted is perpendicular to the aforementioned first direction S1 and second direction S2.

In the illustrated example of the light-emitting device 100, light that is emitted from the plurality of light-emitting elements 20 becomes collimated light that is collimated at least regarding its fast-axis direction (i.e., the direction perpendicular to the first mounting surface 11M), and is emitted through the lens member 40. The lens member 40 includes one lens surface through which the first light 22a, the second light 22b, and the third light 22c are collimated. In this example, the optical axis of the first light 22a (first optical axis 21a) is identical to the optical axis of the lens member 40.

### Second Embodiment

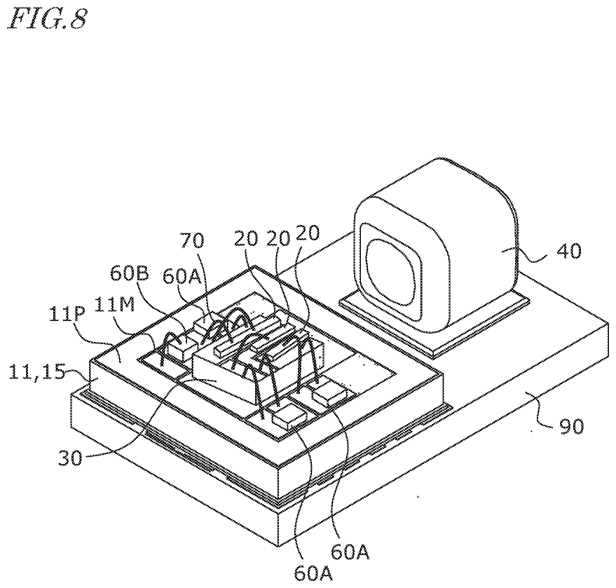

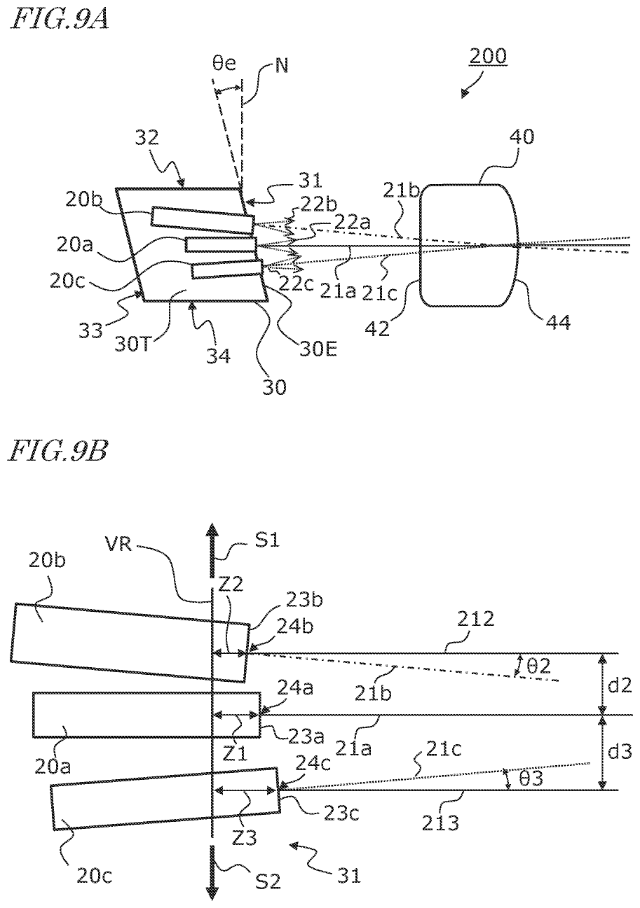

A light-emitting device 200 according to a second embodiment will be described. A perspective view of the light-emitting device 200 is represented by FIG. 1, which also represents a perspective view of the light-emitting device 100. FIG. 8 shows a perspective view of the light-emitting device 200, from which a cap 16 of a package 10 is omitted. FIG. 9A is a top view showing an exemplary shape of a submount on which a plurality of light-emitting elements 20 are mounted. FIG. 9B is a top view showing positional relationship of points of emission of the plurality of light-emitting elements 20.

Similarly to the light-emitting device 100, the light-emitting device 200 includes a plurality of components, including: the package 10, one or more light-emitting elements 20, one or more submounts 30, a lens member 40, one or more protection elements 60A, a temperature measurement element 60B, a plurality of wirings 70, and a substrate 90.

The submount 30 of the light-emitting device 200 has a lateral surface 31 that intersects an upper surface 30T. In addition to this lateral surface 31, the submount 30 also includes lateral surfaces 32, 33 and 34. In the illustrated example, the upper surface of the submount 30 is a parallelogram whose vertex angles are not 90 degrees, in which opposing lateral surfaces 31 and 33 are parallel and opposing lateral surfaces 32 and 34 are also parallel. The shape of the upper surface of the submount 30 does not need to be a parallelogram, but may alternatively be a rhombus, trapezoid, an inequilateral polygon, etc. In the case where the shape of the upper surface of the submount 30 is a parallelogram, when a submount base material is singulated into submounts, efficient use of the submount base material can be made to prevent an unwanted increase in the material cost.

The first light-emitting element 20a, the second light-emitting element 20b, and the third light-emitting element 20c are disposed so that a first point of emission 24a at which first light 22a traveling along the first optical axis 21a is emitted through a first light-emission surface 23a, a second point of emission 24b at which second light 22b traveling along the second optical axis 21b is emitted through a second light-emission surface 23b, and a third point of emission 24c at which third light 22c traveling along the third optical axis 21c is emitted through a third light-emission surface 23c are located outward of the outer edge 30E located at the boundary between the upper surface 30T and the lateral surface 31 of the submount 30.

In a top view, the direction of the first optical axis 21a and the direction in which the outer edge 30E extends intersect each other at an angle other than 90°. In other words, among the four lateral surfaces 31, 32, 33 and 34 of the submount 30, the lateral surface 31 facing the lens member 40 is not orthogonal to the direction of the first optical axis 21a. In a top view, the absolute value of the angle of inclination θe of the lateral surface 31 with respect to a line N perpendicular to the first optical axis 21a is greater than 0 degrees, and e.g., 45 degrees or less.

In the present embodiment, as shown in FIG. 9B, the distance Z1 from the plane VR to the first point of emission 24a of the first light-emitting element 20a is longer than the distance Z2 from the plane VR to the second point of emission 24b of the second light-emitting element 20b. Moreover, the distance Z1 from the plane VR to the first point of emission 24a of the first light-emitting element 20a is shorter than the distance Z3 from the plane VR to the third point of emission 24c of the third light-emitting element 20c.

Since each of the first point of emission 24a, the second point of emission 24b, and the third point of emission 24c located outward of the outer edge 30E located at the boundary between the upper surface 30T and the lateral surface 31 of the submount 30 in a direction towards the lens member 40, portions of light being emitted from the points of emission 24a, 24b and 24c spreading out can be prevented from striking the submount 30 (“unwanted loss”). The longer the distance of each point of emission 24a, 24b or 24c from the lateral surface 31 of the submount 30 is, the smaller the contact area of the corresponding light-emitting element 20a, 20b or 20c and the submount 30 is. Since a larger contact area will allow the heat generated in the light-emitting elements 20a, 20b and 20c to be transmitted to the outside through the submount 30, the contact area is preferably as large as possible. Therefore, the distance of each point of emission 24a, 24b or 24c from the outer edge 30E located at the boundary between the upper surface 30T and the lateral surface 31 of the submount 30 may be set in the range of 0 μm or greater and 50 μm or less, for example.

In the example illustrated in FIG. 9A and FIG. 9B, the distance from the light-incident surface 42 of the lens member 40 to the first point of emission 24a is different from the distance from the light-incident surface 42 of the lens member 40 to the second point of emission 24b, and also different from the distance from the light-incident surface 42 of the lens member 40 to the third point of emission 24c. According to the present embodiment, in the case where the focal length of the lens member 40 differs depending on the wavelength of light, it is possible to dispose the first point of emission 24a, the second point of emission 24b, and the third point of emission 24c in accordance with their respective focal lengths. In one example, the difference between the distance Z1 and the distance Z2 may be set in the range of 5 μm or greater and 60 μm or less, for example. Moreover, the difference between the distance Z1 and the distance Z3 may be set in the range of 5 μm or greater and 60 μm or less, for example.

Thus, in the case where the first point of emission 24a, the second point of emission 24b, and the third point of emission 24c are at different positions along the direction of the optical axis of the lens member 40, the difference between the absolute value of the inclination (angle θ2) of the second optical axis 21b with respect to the first optical axis 21a and the absolute value of the inclination (angle θ3) of the third optical axis 21c with respect to the first optical axis 21a may be 0 degrees, but preferably is greater than 0 degrees. In the case where the distance d2 and the distance d3 are equal, by setting the absolute value of the angle θ2 and the absolute value of the angle θ3 at different values, the first optical axis 21a, the second optical axis 21b, and the third optical axis 21c can be made to intersect at the ‘same’ position. Even in the case where the distance d2 and the distance d3 are different, by adjusting each of the absolute value of the angle θ2 and the absolute value of the angle θ3, the first optical axis 21a, the second optical axis 21b, and the third optical axis 21c can be made to intersect at the ‘same’ position.

Thus, the absolute value of the angle θ2 and the absolute value of the angle θ3, which define the relationship between the inclinations of the first optical axis 21a, the second optical axis 21b, and the third optical axis 21c, may take values that are in accordance with the lens characteristics (e.g., focal length) of the lens member 40, which in turn are determined by the peak wavelength of light traveling along each optical axis.

With the light-emitting device 200 according to the present embodiment, positions at which the first light 22a, the second light 22b, and the third light 22c are incident on the lens member 40 can be brought closer together, and the respective positions of the points of emission can be adjusted to reduce chromatic aberrations caused by the lens member 40. As a result, in a display in which the light-emitting device 200 is used as a light source, blurs of the respective colors of pixels at the imaging plane can be easier to control.

### Third Embodiment

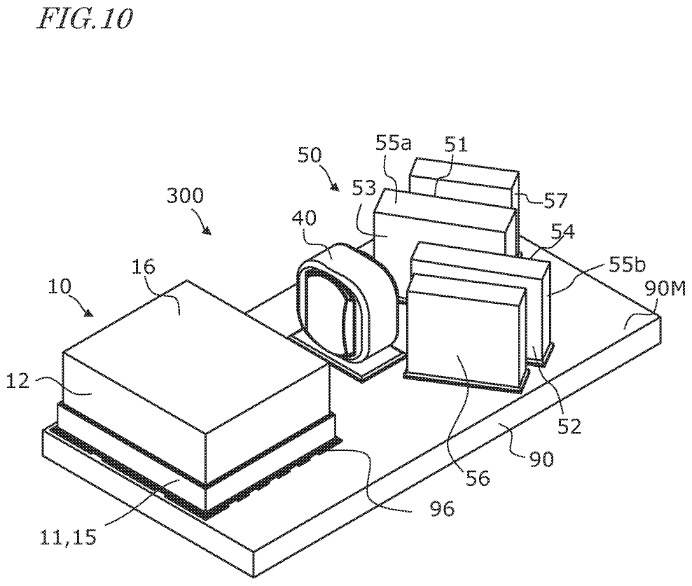

A light-emitting device 300 according to a third embodiment will be described. FIG. 10 and FIG. 11 are diagrams for describing an illustrative implementation of the light-emitting device 300. FIG. 10 is a perspective view of the light-emitting device 300. FIG. 11 is a top view of the light-emitting device 300, from which a cap of a package is omitted.

The light-emitting device 300 includes components similar to those of the light-emitting device 100, and further includes an optical control unit 50 capable of controlling the optical axes 21a, 21b and 21c of first light 22a, second light 22b, and third light 22c having been transmitted through the lens member 40 so that these rays of light become parallel, and preferably coaxial, with one another.

The optical control unit 50 controls the first light 22a, the second light 22b, and the third light 22c incident thereon so that their optical axes are parallel to one another and that at least some of these rays of light overlap with one another. In other words, the optical control unit 50 controls the first light 22a, the second light 22b, and the third light 22c, which have traveled along non-parallel optical axes, so that the first light 22a, the second light 22b, and the third light 22c will travel along optical axes that are parallel to one another. In the illustrated example, the optical control unit 50 includes a plurality of optical members (reference numerals 55a, 55b, 56 and 57 in the figure). With the plurality of optical members, the optical control unit 50 performs an optical control that combines selective reflection and selective transmission, so that their optical axes become parallel to one another. With the optical control unit 50, the first light 22a, the second light 22b, and the third light 22c can become coaxial light before they are emitted from the optical control unit 50.

The optical control unit 50 is configured so that the first light 22a, the second light 22b, and the third light 22c having passed through the lens member 40 are incident thereon, and that the first light 22a, the second light 22b, and the third light 22c are emitted therefrom in such a manner that their first optical axis 21a, second optical axis 21b, and third optical axis 21c are parallel to one another.

In the light-emitting device 300, in a top view, the first light 22a traveling along the first optical axis 21a and the second light 22b traveling along the second optical axis 21b intersect only after having traveled a longer optical path length than the optical path length that just reaches the exit surface 44 of the lens member 40. In a top view, the first light 22a traveling along the first optical axis 21a and the third light 22c traveling along the third optical axis 21c intersect only after having traveled a longer optical path length than the optical path length that just reaches the exit surface 44 of the lens member 40. In a top view, the second light 22b traveling along the second optical axis 21b and the third light 22c traveling along the third optical axis 21c intersect only after having traveled a longer optical path length than the optical path length that just reaches the exit surface 44 of the lens member 40.

In the light-emitting device 100, in a top view, the first light 22a traveling along the first optical axis 21a and the second light 22b traveling along the second optical axis 21b intersect while traveling along an optical path from the point of emission on the lens member 40 to the point of incidence on the optical control unit 50. In a top view, the first light 22a traveling along the first optical axis 21a and the third light 22c traveling along the third optical axis 21c intersect while traveling along an optical path from the point of emission on the lens member 40 to the point of incidence on the optical control unit 50. In a top view, the second light 22b traveling along the second optical axis 21b and the third light 22c traveling along the third optical axis 21c intersect while traveling along an optical path from the point of emission on the lens member 40 to the point of incidence on the optical control unit 50.

The second light 22b traveling along the second optical axis 21b of the second light-emitting element 20b, which is at a position that is separated in the first direction S1 from the first light-emitting element 20a, is incident on the optical control unit 50 at a position that is separated in the second direction S2 from the first optical axis 21a. The third light 22c traveling along the third optical axis 21c of the third light-emitting element 20c, which is at a position that is separated in the second direction S2 from the first light-emitting element 20a, is incident on the optical control unit 50 at a position that is separated in the first direction S1 from the first optical axis 21a.

By ensuring that, in a top view, the optical axes of the plurality of rays of light intersect at a position between the lens member 40 and the optical control unit 50, the distance between the optical axes of the two rays of light when incident on the optical control unit 50 can be made narrower than that in the case where they are allowed to intersect before passing through the lens member 40.

Thus, in the present embodiment, rays of light traveling on optical axes that intersect one another in a top view have respectively different peak wavelengths. Therefore, a plurality of surfaces that have different reflection characteristics or different transmission characteristics depending on wavelength are provided in order to place their optical axes in parallel directions.

Although there is no limitation as to the configuration of the optical control unit 50 exhibiting such a function, for example, as is illustrated in FIGS. 10 and 11, a plurality of optical members each in the shape of a plate may be provided. In the illustrated example of the light-emitting device 300, the optical control unit 50 includes two first optical members 55a and 55b, the second optical member 56, and the third optical member 57.

The plurality of rays of light incident on the optical control unit 50 are light of respectively different peak wavelengths. Alternatively, the plurality of rays of light incident on the optical control unit 50 may be light of respectively different colors. With the plurality of optical members, a plurality of regions (optical control regions) for performing selective optical control for the plurality of rays of light are created.

Each optical control region may be formed on the surface (a preferably flat and smooth surface) of an optical member. For example, an optical member that is made of a transparent material (e.g., a glass or a plastic) that transmits visible light may be formed on the surface (principal surface) of a transparent main body, by depositing a multilayer dielectric film with a thin-film deposition technique such as sputtering. Each optical member may be implemented as a dichroic mirror, for example.

In the light-emitting device 300, the optical control unit 50 is disposed on the second substrate 90. The optical control unit 50 is mounted on the second mounting surface 90M, whereby the optical control unit 50 becomes supported by the second mounting surface 90M. Note that the optical control unit 50 may alternatively be mounted on the first substrate 15.

Light emitted from the plurality of light-emitting elements 20 is incident on the optical control unit 50. Specifically, a plurality of rays of light whose optical axes are not parallel to one another are incident on the optical control unit 50. The light that is incident on the optical control unit 50 has been collimated through the lens member 40.

In a top view, the plurality of optical control regions of the optical control unit 50 are inclined with respect to a straight line that is parallel to the first optical axis 21a. The angle of this inclination may be set in the range of 35° or greater and 70° or less, for example.

In a top view, the plurality of optical members (55a, 55b, 56, 57) of the optical control unit 50 are disposed in an oblique direction with respect to the first optical axis 21a. In the illustrated example, in a top view, two adjacent optical members satisfy the following relationship: on a straight line that passes through and is parallel to the optical control region associated with one optical member, the other optical member does not exist, and the one optical member does not exist on an imaginary line that passes through the optical control region associated with the other optical member. This relationship is satisfied by all of the optical members constituting the optical control regions. Arranging a plurality of optical members of similar shapes will facilitate this implementation.

In the illustrated example of the light-emitting device 300, the first light 22a, the second light 22b, and the third light 22c that have passes through one lens surface of the lens member 40 are incident on the optical control unit 50. The optical control unit 50 includes four optical members 55a, 55b, 56 and 57, and thus the first light 22a, the second light 22b, and the third light 22c are emitted from the optical control unit 50 in such a manner that their optical axes are parallel to one another.

The optical control unit 50 includes two first optical members 55a and 55b, the second optical member 56, and the third optical member 57. The two first optical members 55a and 55b constitute at least four optical control regions. Herein, the four optical control regions are distinguished as the first region 51, the second region 52, the third region 53, and the fourth region 54 for the sake of explanation.

The two first optical members 55a and 55b each have a first surface facing the lens member 40, and a second surface that is the opposite surface. The four optical control regions exist on the first surfaces and second surfaces of the two first optical members 55a and 55b.

The third region 53 is formed on the first surface of the first optical member 55a, whereas the first region 51 is formed on the second surface of the first optical member 55a. The second region 52 and the fourth region 54 are provided on different surfaces of the same first optical member 55b. The second region 52 is formed on the first surface of the first optical member 55b, whereas the fourth region 54 is formed on the second surface of the first optical member 55b.

The second optical member 56 includes a reflection surface 56M. The third optical member 57 includes a reflection surface 57M. The reflection surface 56M and the reflection surface 57M have a positional relationship such that they face each other via the two first optical members 55a and 55b. The two first optical members 55a and 55b are disposed between a plane that includes the reflection surface 56M of the second optical member 56 and a plane that includes the reflection surface 57M of the third optical member 57.

The first region 51 reflects the first light 21a, and transmits the third light 21c. The second region 52 reflects the first light 21a, and transmits the second light 21b. The third region 53 reflects the second light 21b, transmits the first light 21a, and transmits the third light 21c. The fourth region 54 reflects the third light 21c, transmits the first light 21a, and transmits the second light 21b. The reflection surface 56M reflects the second light 21b. The reflection surface 57M reflects the third light 21c.

The exemplary configuration of the optical control unit 50 is only an example, and the optical control unit 50 may have any other configuration. By employing an optical control unit that controls the optical axes of light transmitted through the lens member 40 in accordance with their light colors, the alignment of various optics used in the display with respect to the optical axis can be facilitated when the light-emitting device is used as a light source of a display, for example.

### Fourth Embodiment

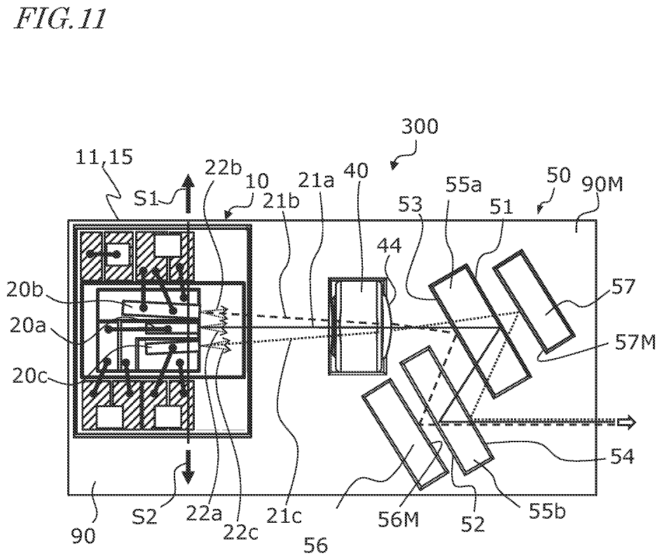

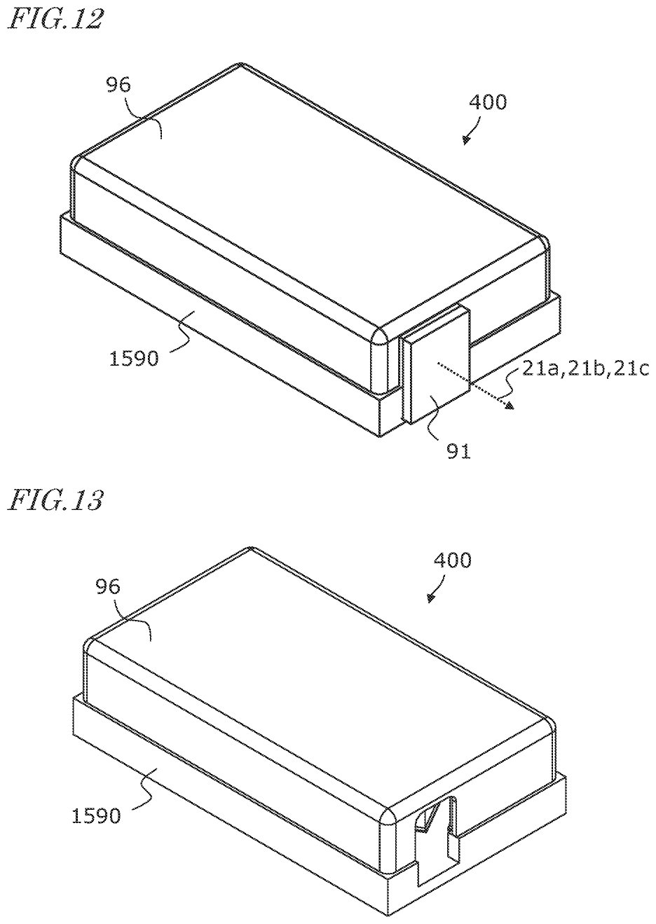

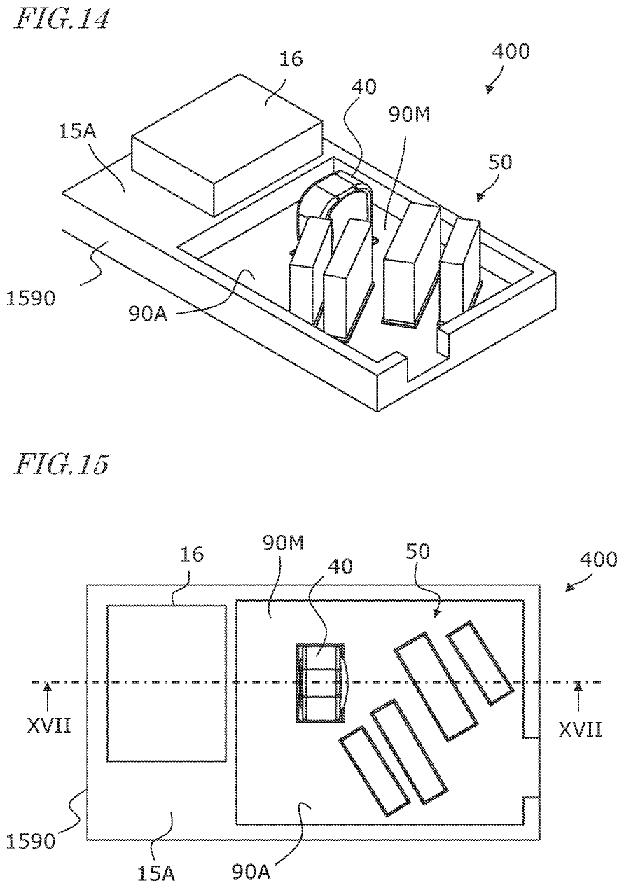

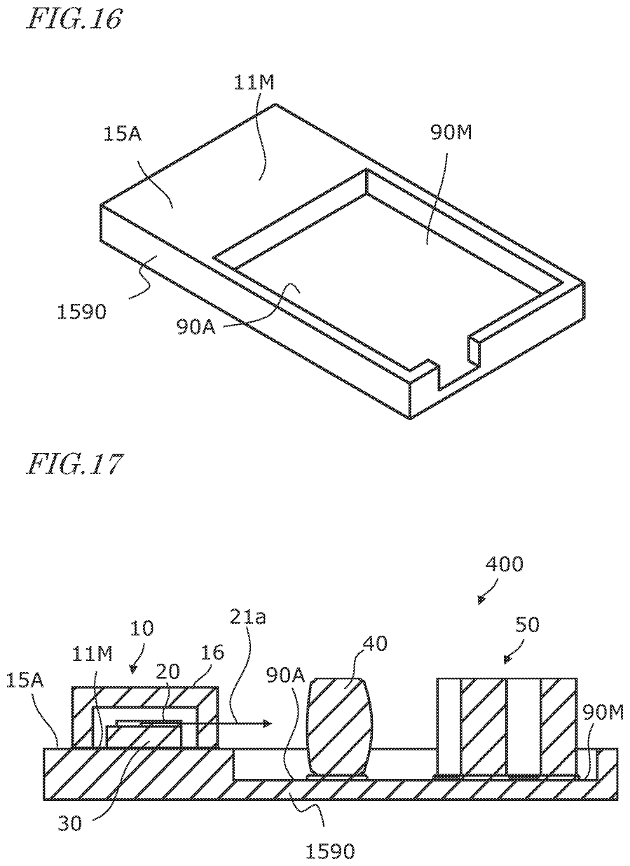

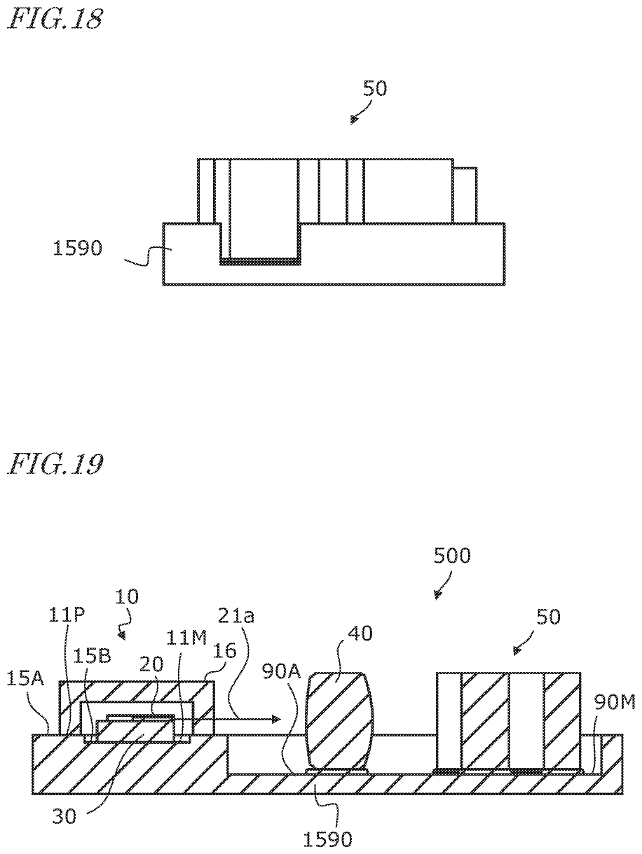

A light-emitting device 400 according to a fourth embodiment will be described. FIG. 12 to FIG. 18 are diagrams for describing an illustrative implementation of the light-emitting device 400. FIG. 12 is a perspective view of the light-emitting device 400. FIG. 13 is a perspective view of the light-emitting device 400, from which a cover is omitted. FIG. 14 is a perspective view of the light-emitting device 400, resulting by omitting a second cap from the state depicted in FIG. 13. FIG. 15 is a top view of the light-emitting device 400, resulting by omitting the second cap and the cover from the state depicted in FIG. 13. FIG. 16 is a perspective view of a substrate included in the light-emitting device 400. FIG. 17 is a cross-sectional view taken along cross-sectional line XVII-XVII in FIG. 15. FIG. 18 is a side view corresponding to FIG. 14, as viewed from the cover side.

The light-emitting device 400 according to the present embodiment differs in that a substrate 1590 having a stepped shape is employed instead of the first substrate 15 and the second substrate 90 in each of the embodiments described above. Moreover, in addition to a cap 16 that surrounds one or more light-emitting elements 20 but does not surround the lens member 40 (hereinafter referred to as the first cap 16), the light-emitting device 400 includes a cap 96 that surrounds the package 10, the lens member 40, and the optical control unit 50 (hereinafter referred to as the second cap 96). Furthermore, the light-emitting device 400 includes a cover 91.

(Substrate 1590)

The substrate 1590 has a first upper surface 15A and a second upper surface 90A. The first upper surface 15A is a surface on which the first mounting surface 11M is provided, whereas the second upper surface 90A is a surface on which the second mounting surface 90M is provided. As has already been described with reference to the other embodiments, one or more light-emitting elements 20 are disposed on the first mounting surface 11M, whereas the lens member 40 and the optical control unit 50 are disposed on the second mounting surface 90M. The first upper surface 15A is located upward from the second upper surface 90A.

In a top view, the substrate 1590 has a rectangular outer shape. This rectangle has shorter sides and longer sides. In a top view, the second upper surface 90A is surrounded by the first upper surface 15A. The first upper surface 15A surrounds a portion of the second upper surface 90A. The portion that is not surrounded by the first upper surface 15A includes a portion where the cover 91 is provided. In the illustrated example of the light-emitting device 400, except for the portion where the cover 91 is provided, the second upper surface 90A is surrounded by the first upper surface 15A. The portion where the cover 91 is provided is located on the opposite side of the second upper surface 90A from the side where the one or more light-emitting elements 20 are disposed.

The portion where the cover 91 is provided has a concave shape in a lateral view. The part of the upper surface located at the top of the concave shape is the first upper surface 15A, whereas the part of the upper surface located at the bottom of the concave shape is the second upper surface 90A. The length of the second upper surface 90A within this concave shape is ½ or less of the length of the substrate 1590 along the same direction. In a lateral view, the second upper surface 90A within this recessed shape is provided at a position that is not intersected by an imaginary line that passes through the center of the width of the substrate 1590 along a direction parallel to the second upper surface 90A and that extends along a direction perpendicular to the second upper surface 90A. Simply stated, the recessed shape is located at a position that is deviated to one side of the center of the lateral surface of the substrate 1590 in which the recessed shape is created.

In the case of the substrate 1590, a plurality of wiring regions 14 to be provided on the first mounting surface 11M may be electrically connected to wiring regions that are provided on the lower surface of the base portion 1590, through via holes extending inside the substrate 1590.

The substrate 1590 can be made of a similar material to that of the substrate 15 or the substrate 90. For example, the substrate 1590 can be made of a ceramic as a main material. The substrate 1590 can be made of a light-shielding material that shields light. The substrate 1590 can be made of a ceramic of light-shielding nature as a main material.

(Second Cap 96)

The second cap 96 is bonded to the first upper surface 15A of the substrate 1590. In a lateral view, the second cap 96 has a recessed shape at a position corresponding to the recessed shape in the substrate 1590. As the substrate 1590 and the second cap 96 are bonded together, an opening is created that is defined by these respective recessed shapes.

The second cap 96 can be made of a light-shielding material that shields light. For example, the second cap 96 can be produced by forming a shape of the second cap 96 from glass, and providing a light-shielding film on its surface.

(Cover 91)

The cover 91 is light-transmissive. The cover 91 has a flat plate shape. The cover 91 is bonded to the substrate 1590 and the second cap 96. The cover 91 covers the opening that is defined by the substrate 1590 and the second cap 96 being bonded together. As the cover 91 is bonded, the space accommodating the lens member 40 becomes a closed space.

(Light-Emitting Device 400)

Next, the light-emitting device 400 will be described.

The space accommodating the one or more light-emitting elements 20 is sealed by the substrate 1590 and the first cap 16. As a result, a package structure surrounding the light-emitting element(s) 20 is created. Moreover, the space accommodating the package structure, the lens member 40, and the optical control unit 50 is surrounded by the substrate 1590 and the second cap 96. However, the cover 91 is bonded to the aforementioned opening in a manner of allowing the light emitted from the optical control unit 50 to be emitted to the outside.

In a lateral view, a first optical axis 21a of first light 22a, a second optical axis 21b of second light 22b, and a third optical axis 21c of third light 22c emitted from the optical control unit 50 are contained in (i.e., fit within) the opening over which the cover 91 is provided. In a lateral view, the respective main portions of the first light 22a, the second light 22b, and the third light 22c emitted from the optical control unit 50 are contained in the opening over which the cover 91 is provided. The first light 22a, the second light 22b, and the third light 22c are emitted through the cover 91.

In a lateral view, the point of emission of light of the light-emitting element 20 that is located at the farthest position from the cover 91 is not contained in the opening over which the cover 91 is provided. For example, the second light-emitting element 20b may be the light-emitting element 20 that is located at the farthest position from the cover 91. This can suppress leakage of light through unwanted sites. In an alternative arrangement, in a lateral view, the point of emission of light from the first light-emitting element 20a may not be contained in the opening over which the cover 91 is provided.

### Fifth Embodiment

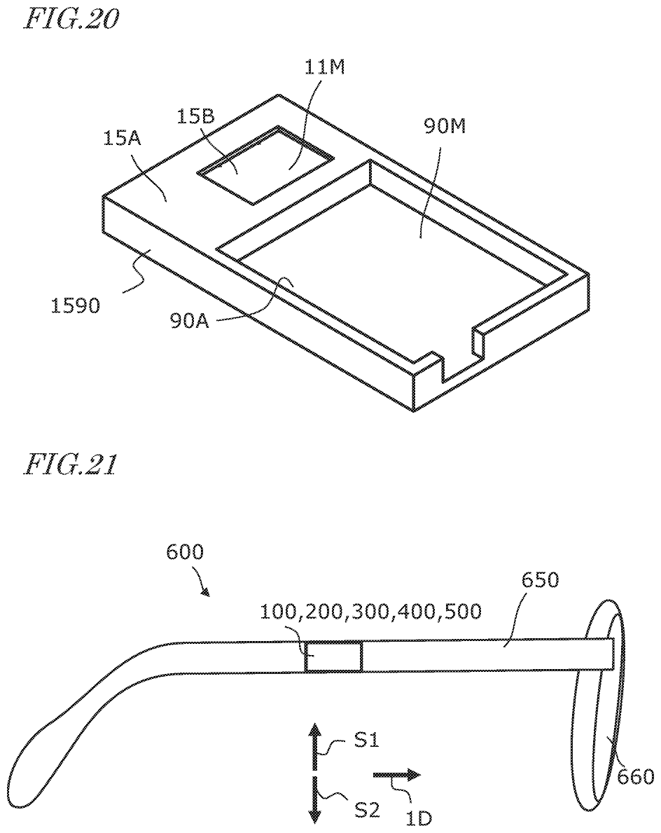

A light-emitting device 500 according to a fifth embodiment will be described. FIG. 19 is a diagram for describing an illustrative implementation of the light-emitting device 500. FIG. 19 is a cross-sectional view of the light-emitting device 500. The cross section of the light-emitting device 500 in this cross-sectional view is at a position corresponding to that in FIG. 17 directed to the fourth embodiment. FIG. 20 is a perspective view of a substrate 1590 included in the light-emitting device 500.

The substrate 1590 of the light-emitting device 500 differs from the substrate 1590 of the fourth embodiment in that the first mounting surface 11M and the peripheral region 11P are provided on different planes. The substrate 1590 of the light-emitting device 500 is made so that the portion of its upper surface on which the first mounting surface 11M is provided is located downward from the portion of its upper surface on which the peripheral region 11P is provided. The portion of the upper surface on which the peripheral region 11P is provided is also the bonding surface to which the second cap 96 is bonded. Therefore, for consistency with the fourth embodiment, the portion of the upper surface on which the peripheral region 11P is provided will be referred to as the first upper surface 15A. On the other hand, the portion of the upper surface on which the first mounting surface 11M is provided is referred to as the third upper surface 15B.

In a top view, the third upper surface 15B is surrounded by the first upper surface 15A. The third upper surface 15B is located downward from the first upper surface 15A by 50 μm or greater and 500 μm or less. Providing the first upper surface 15A upward from the third upper surface 15B allows the wiring region 14 to expand to immediately under the peripheral region 11P and reduce the size of the wiring region 14 exposed on the third upper surface 15B. This can contribute to the downsizing of the light-emitting device 500.

The length (thickness) of the submount 30 along the top-bottom direction is greater than the difference in height between the first upper surface 15A and the third upper surface 153. Specifically, the thickness of the submount 30 may be greater by a value in the range of 200 μm or greater and 1000 μm or less than the difference in height between the first upper surface 15A and the third upper surface 153. As a result, the height of the emission point of each light-emitting element 20 can be raised so that the main portion of light emitted therefrom will not be radiated onto the first upper surface 15A.

<Head-Mounted Display>

FIG. 21 is a side view schematically showing an exemplary configuration of a head-mounted display 600 that includes a light-emitting device 100 (200, 300, 400, 500) according to an embodiment of the present disclosure. Although the light-emitting device 100 will be taken as an example below, the head-mounted display 600 may include any of the light-emitting devices 200, 300, 400 and 500 instead of the light-emitting device 100. The head-mounted display 600 includes a temple 650, and a waveguide 660 connected to the temple 650. The waveguide 660 includes a light-emitting region such as a diffraction grating. Laser light that is incident on the waveguide 660 may be emitted through the light-emitting region of the waveguide 660 toward the retina of an eye of a user.

One end of the temple 650 is located on the waveguide 660 side, i.e., closer to the surface of the user, while the other end of the temple 650 is located on the opposite side to the waveguide 660, i.e., closer to an ear of the user. In FIG. 21, the direction along these ends of the temple 650 is parallel to the direction of the optical axis of the lens member 40. On the basis of the user wearing the head-mounted display 600, the direction of the optical axis of the lens member 40 is substantially parallel to the direction from the ear to the eye of the user (or the opposite direction thereto) in a lateral view.

In the exemplary head-mounted display 600 shown in FIG. 21, the light-emitting device 100 is supported on the inside of the temple 650. Although FIG. 21 illustrates the light-emitting device 100 as if appearing on the side shown, the actual appearance of the light-emitting device 100 may be obscured from the outside. The size of the light-emitting device 100 along a direction that is parallel to the first direction S1 and the second direction S2 may be e.g. 3 mm or greater and 15 mm or less, that is, smaller than the size of the temple 650 along the direction in which it extends (i.e., a direction 1D perpendicular to the first direction S1 and the second direction S2 as shown in FIG. 21).

Preferably, the light-emitting device 100 is mounted on the head-mounted display 600 in such a manner that the direction of the optical axis of the lens member of the light-emitting device 100 and the direction in which the temple of the head-mounted display 600 extends are parallel. With the light-emitting device 100 with reduction in size along the direction perpendicular to the optical axis of the lens member, the width of the temple 650 can be reduced. Note that, as shown in FIG. 21, the temple 650 has a length that sufficiently covers the distance from the eye to the ear of the user; therefore, so long as the size of the lens member of the light-emitting device 100 along the optical axis direction is somewhat small, any further reduction will not contribute to the downsizing of the head-mounted display 600.

In this embodiment, collimated beams of the first light, the second light, and the third light can be emitted in a coaxial manner through a narrow region from the light-emitting device 100. The first light, the second light, and the third light may be laser beams of any of red, green, and blue colors. The laser beam of each color is used for a MEMS device (e.g., a micromirror) for scanning, so as to travel within the waveguide 660 and eventually form an image on the retina(s) of the eye(s) of the user. Displaying of a color image may be performed by a field sequential method. In that case, the first light, the second light, and the third light are to be emitted in a sequential manner. In order to monitor the intensities of the first light, the second light, and the third light, a photodetector such as a photodiode may be utilized for each color of light. The photodetectors may be disposed on the outside or on the inside of the light-emitting device 100. The photodetectors may be disposed inside the package 10 of the light-emitting device 100.

Under a method where an image is to be formed on the retina, the beam convergence spot on the retina is preferably as small as possible, for achieving a high resolution. From this standpoint, a longer focal length of the lens member is preferable. On the other hand, a longer focal length may result in less light being incident on the lens surface of the lens member 40 because of spread of light, thus causing an increased loss of light. In the case of laser light, there is a wider spread of light along the fast-axis direction than along the slow-axis direction; therefore, the fast-axis direction is more susceptible to such losses.

Moreover, in a near-field pattern, the shape of a laser light spot will be larger along the slow-axis direction than along the fast-axis direction. Therefore, if a lens having an identical focal length along both the slow axis and the fast axis is used for collimation, the convergence spot on the retina will be larger along the slow-axis direction.

Therefore, the lens surface of the lens member 40 is preferably designed so that the focal length along the slow-axis direction is longer than the focal length along the fast-axis direction. This will allow the size of the convergence spot along the slow-axis direction to be reduced without inducing an increased loss of laser light.

Although embodiments of the present invention have been described above, light-emitting devices according to the present invention are not to be strictly limited to the light-emitting devices of the embodiments. In other words, the present invention can be carried out without being limited to the outer shapes and structures of the light-emitting devices disclosed in the embodiments. For example, the light-emitting device may lack the protection elements. The present invention is applicable without requiring all of the components. For example, when a claim does not recite some of the components of a light-emitting device according to an embodiment, it is intended that such components permit design choices by one skilled in the art (e.g., replacement, omission, changes in shape, changes in material) and that the invention defined by the claim is still applicable.

Light-emitting devices according to embodiments can be used for head-mounted displays, projectors, illuminations, displays, and the like.

What is claimed is:

1. A light-emitting device comprising:
a first light-emitting element including a first light-emission surface through which first light is emitted along a first optical axis;
a second light-emitting element disposed apart from the first light-emitting element in a first direction that is perpendicular to the first optical axis such that a reference plane parallel to the first light-emission surface and intersecting the first light-emitting element intersects the second light-emitting element, the second light-emitting element including a second light-emission surface through which second light is emitted along a second optical axis that is inclined with respect to the first optical axis in a second direction opposite to the first direction; and
a third light-emitting element disposed apart from the first light-emitting element in the second direction such that the reference plane intersects the third light-emitting element, wherein the third light-emitting element includes a third light-emission surface through which third light is emitted along a third optical axis that is inclined with respect to the first optical axis in the first direction.

2. The light-emitting device of claim 1, further comprising:
a lens member having an incident surface on which the first light, the second light, and the third light respectively emitted from the first light-emitting element, the second light-emitting element, and the third light-emitting element are incident, wherein:
two of (i) a first point of incidence at which the first light traveling along the first optical axis is incident on the incident surface of the lens member, (ii) a second point of incidence at which the second light traveling along the second optical axis is incident on the incident surface of the lens member, and (iii) a third point of incidence at which the third light traveling along the third optical axis is incident on the incident surface of the lens member, are closer to each other than corresponding two of (i) a first point of emission at which the first light traveling along the first optical axis is emitted through the first light-emission surface, (ii) a second point of emission at which the second light traveling along the second optical axis is emitted through the second light-emission surface, and (iii) a third point of emission at which the third light traveling along the third optical axis is emitted through the third light-emission surface.

3. The light-emitting device of claim 2, wherein:
the lens member has a single lens surface through which the first light, the second light, and the third light are emitted.

4. The light-emitting device of claim 1, wherein:
the second optical axis has an inclination with respect to the first optical axis of greater than 0 degrees and 30 degrees or less; and
the third optical axis has an inclination with respect to the first optical axis of greater than 0 degrees and 30 degrees or less.

5. The light-emitting device of claim 1, wherein:
a difference between an absolute value of the inclination of the second optical axis with respect to the first optical axis and an absolute value of the inclination of the third optical axis with respect to the first optical axis is 0 degrees or greater and 5 degrees or less.

6. The light-emitting device of claim 4, wherein:
a difference between an absolute value of the inclination of the second optical axis with respect to the first optical axis and an absolute value of the inclination of the third optical axis with respect to the first optical axis is 0 degrees or greater and 5 degrees or less.

7. The light-emitting device of claim 1, further comprising:
an optical control unit on which the first light, the second light, and the third light having passed through the lens member are incident, wherein the optical control unit is configured to parallelize the first light, the second light, and the third light.

8. The light-emitting device of claim 7, wherein:
the second light traveling along the second optical axis is incident on the optical control unit at a position that is separated in the second direction from the first optical axis; and
the third light traveling along the third optical axis is incident on the optical control unit at a position that is separated in the first direction from the first optical axis.

9. The light-emitting device of claim 1, further comprising:
a plurality of dichroic mirrors on which the first light, the second light, and the third light having passed through the lens member are incident, wherein the plurality of dichroic mirrors are configured to parallelize the first light, the second light, and the third light.

10. The light-emitting device of claim 9, wherein:
the second light traveling along the second optical axis is incident on a surface of the plurality of dichroic mirrors at a position that is separated in the second direction from the first optical axis; and
the third light traveling along the third optical axis is incident on a surface of the plurality of dichroic mirrors at a position that is separated in the first direction from the first optical axis.

11. The light-emitting device of claim 1, further comprising:
a submount on which the first light-emitting element, the second light-emitting element, and the third light-emitting element are disposed.

12. The light-emitting device of claim 11, wherein:
the submount has an upper surface and a lateral surface intersecting the upper surface;
the first light-emitting element, the second light-emitting element, and the third light-emitting element are disposed so that, in a top view, (i) the first point of emission at which the first light traveling along the first optical axis is emitted through the first light-emission surface, (ii) the second point of emission at which the second light traveling along the second optical axis is emitted through the second light-emission surface, and (iii) the third point of emission at which the third light traveling along the third optical axis is emitted through the third light-emission surface, are located outward of an outer edge that is located at a boundary between the upper surface and the lateral surface of the submount; and
in a top view, the first optical axis direction and a direction in which the outer edge extends intersect each other at an angle other than 90°.

13. The light-emitting device of claim 10, wherein:
the upper surface of the submount has a shape of a parallelogram having vertex angles, none of the vertex angles being 90 degrees.

14. The light-emitting device of claim 1, wherein: the first light-emitting element, the second light-emitting element, and the third light-emitting element are semiconductor laser elements.
